(19) United States
(12) Patent Application Publication
(10) Pub. No.: US 2002/0106876 A1
(43) Pub. Date: Aug. 8, 2002

(54) Method of forming a buffer layer over a polysilicon gate

(76) Inventor: Wei-Wen Chen, Hsin-Chu City (TW)

Correspondence Address: POWELL, GOLDSTEIN, FRAZER & MURPHY LLP, P.O. BOX 97233, WASHINGTON, DC, 20090-7223, US

(21) Appl. No.: 09/776,737

(22) Filed: Feb. 5, 2001

(51) Int. Cl. H01L 21/3205

(52) U.S. Cl. 438/585

(57) ABSTRACT

This invention relates to a method for forming a buffer layer, more particularly, to the method for forming a mixed layer which comprises silicon oxynitride and silicon dioxide to be a buffer layer over a polysilicon gate by using a nitrogen ions implantation and a thermal oxidation. The present invention uses the ions implantation to implant nitrogen ions to the surface of the polysilicon gate at first. After passing through a thermal oxide process, the hard mixed layer, which comprises silicon oxynitride and silicon dioxide, is formed over the surface of the polysilicon gate. The mixed layer, which comprises silicon oxynitride and silicon dioxide, formed over the polysilicon gate can prevent another ions entering to the polysilicon gate to affect the critical dimention of the polysilicon gate.

### BACKGROUND OF THE INVENTION

1. Field of the Invention

This invention relates to a method for forming a buffer layer, more particularly, to the method for forming a mixed layer which comprises silicon oxynitride and silicon dioxide to be a buffer layer over a polysilicon gate by using a nitrogen ions implantation and a thermal oxidation. The mixed layer, which comprises silicon oxynitride and silicon dioxide, formed over the polysilicon gate by using the present invention method can prevent the stress defects to be generated in the polysilicon gate and can prevent another ions entering to the polysilicon gate to affect the critical dimention of the polysilicon gate.

2. Description of the Prior Art

In general, when a spacer is formed over the polysilicon gate, most used material of the spacer is an insulating material to decrease the probability of generating the electric leakage defects in the polysilicon gate. A buffer layer is usually formed outside the polysilicon gate to increase the combined ability between the spacer and the polysilicon gate and to prevent the electric leakage and stress defects to be generated in the polysilicon gate. The most used insulating material of the spacer is silicon nitride and the combined ability between silicon nitride and polysilicon is very low. Therefore, if a buffer layer is not formed outside the polysilicon gate, a vacant space is usually formed between the polysilicon gate and the spacer to affect the qualities of the semiconductor elements.

The function of the buffer layer is to be a interface between the polysilicon gate and the spacer to increase the combined qualities between the polysilicon gate and the spacer. This condition can prevent the electric leakage and stress defects to be generated in the polysilicon gate. Therefore, the material of the buffer layer must have finer combined ability with the polysilicon gate and the spacer to reach its efficiency.

In general, the most used material of the buffer layer is silicon dioxide, because silicon dioxide has finer combined ability with the polysilicon gate and the spacer. The traditional method for forming the silicon dioxide layer to be the buffer layer over the polysilicon gate is to use the thermal oxide process. At first, a wafer which comprises a decided dimension polysilicon gate on the substrate is placed into the chamber of the furnace. When the temperature of the chamber reaches to about 700° C., oxygen is transported. In the process, the oxygen atoms permeate to the surface of the polysilicon gate and react to become a silicon dioxide thin layer to be the buffer layer.

The silicon dioxide layer, which is formed by using the thermal oxide process, can combine the polysilicon gate and the spacer successfully and can prevent the electric leakage and stress defects to be generated in the polysilicon gate. But the oxygen atoms are hardly controlled in the thermal oxide process. In the thermal oxide process, the oxygen atoms will easily cause the over depth permeation and will react to the silicon atoms which are inside the polysilicon gate to form the silicon dioxide layer. This condition will reduce the original dimension of the polysilicon gate to affect the electricity of the polysilicon gate and further to decrease the qualities of the semiconductor elements.

The buffer layer can also formed by using the chemical vapor deposition process to form a mixed layer, which comprises silicon dioxide and silicon oxynitride, over the polysilicon gate. But the structure of the mixed layer is looser. When the polysilicon gate continues to proceed the making spacer process, the ions of the spacer can break through the mixed layer and enter to the inside the polysilicon gate to affect its electricity. Therefore, the mixed layer, which comprises silicon dioxide and silicon oxynitride, formed by using chemical vapor deposition process must be passed through a rethermal oxide process to increase the density of the mixed layer. In the rethermal oxide process, the oxygen atoms will still permeate to inside the polysilicon gate and will affect the critical dimension of the polysilicon gate. Therefore, the buffer layer is must formed over the polysilicon gate by using the present invention method.

### SUMMARY OF THE INVENTION

In accordance with the above-mentioned invention backgrounds, the traditional method can not form a suitable buffer layer over the polysilicon gate. The present invention provides a method for forming a mixed layer, which comprises silicon oxynitride and silicon dioxide, to be the buffer layer over a polysilicon gate by using a nitrogen ions implantation and a thermal oxidation to control the critical dimension of the polysilicon gate.

The second objective of this invention is to simplify the steps of the process and to increase the efficiency of the process by forming a mixed layer, which comprises silicon oxynitride and silicon dioxide, to be the buffer layer over a polysilicon gate by using a nitrogen ions implantation and a thermal oxidation.

The third objective of this invention is to reduce the extension or the diffusion areas of the source/drain by forming a mixed layer, which comprises silicon oxynitride and silicon dioxide, to be the buffer layer over a polysilicon gate by using a nitrogen ions implantation and a thermal oxidation.

The fourth objective of this invention is to reduce the bird's beak enlargement in the gate oxide layer by forming a mixed layer, which comprises silicon oxynitride and silicon dioxide, to be the buffer layer over a polysilicon gate by using a nitrogen ions implantation and a thermal oxidation.

It is a further objective of this invention is to increase the qualities of the semiconductor elements by forming a mixed layer, which comprises silicon oxynitride and silicon dioxide, to be the buffer layer over a polysilicon gate by using a nitrogen ions implantation and a thermal oxidation.

In according to the foregoing objectives, the present invention provides a method for forming a mixed layer, which comprises silicon oxynitride and silicon dioxide, to be the buffer layer over a polysilicon gate by using a nitrogen ions implantation and a thermal oxidation. The buffer layer can prevent the oxygen atoms permeating to inside the polysilicon gate to affect its dimension and further to affect the electricity of the semiconductor elements. The buffer layer can also restrain the oxygen atoms to pierce through the gate oxide layer, which is at the bottom of the polysilicon gate, and silicon substrate and can reduce the bird's beak area in the gate oxide layer and the diffusion region of the source/drain. The buffer layer can further increase the qualities of the semiconductor elements. The present invention method can decrease the steps of the traditional method and can raise the proceeding rate of the process and the throughput.

### BRIEF DESCRIPTION OF THE DRAWINGS

In the accompanying drawing forming a material part of this description, there is shown:

FIG. 1 shows a diagram in forming a gate oxidelayer and a polysilicon layer on a substrate of a wafer;

FIG. 2 shows a diagram in forming a mask which is located at the place of a polysilicon gate on the polysilicon layer;

FIG. 3 shows a diagram in forming a polysilicon gate on the substrate of the wafer;

FIG. 4 shows a diagram in implanting the nitrogen ions to the surface of the polysilicon gate; and

FIG. 5 shows a diagram in forming a mixed layer, which comprises silicon oxynitride and silicon dioxide, over the surface of the polysilicon gate after passing through a thermal oxide process.

### DESCRIPTION OF THE PREFERRED EMBODIMENT

The foregoing aspects and many of the attendant advantages of this invention will become more readily appreciated as the same becomes better understood by reference to the following detailed description, when taken in conjunction with the accompanying drawings, wherein:

In traditional, the silicon dioxide layer, which is formed by using the thermal oxide process, and the mixed layer, which comprises silicon oxynitride and silicon dioxide and is formed by using the chemical vapor deposition process, can not be the suitable buffer layer to restrain the oxygen atoms permeating into the polysilicon gate to affect the original dimension of the polysilicon gate. This condition can further affect the electricity of the semiconductor elements. The oxygen atoms which has permeated into the polysilicon gate can still permeate to the gate oxide layer which is at the bottom of the polysilicon gate and the substrate. This condition will make the bird's beak area be generated in the gate oxide layer and will enlarge the region of the source/drain to affect the qualities of the semiconductor elements. Therefore, the present invention uses the nitrogen ions implantation and the thermal oxidation to form a mixed layer, which comprises silicon oxynitride and silicon dioxide, to be the buffer layer over a polysilicon gate to increase the qualities of the semiconductor elements.

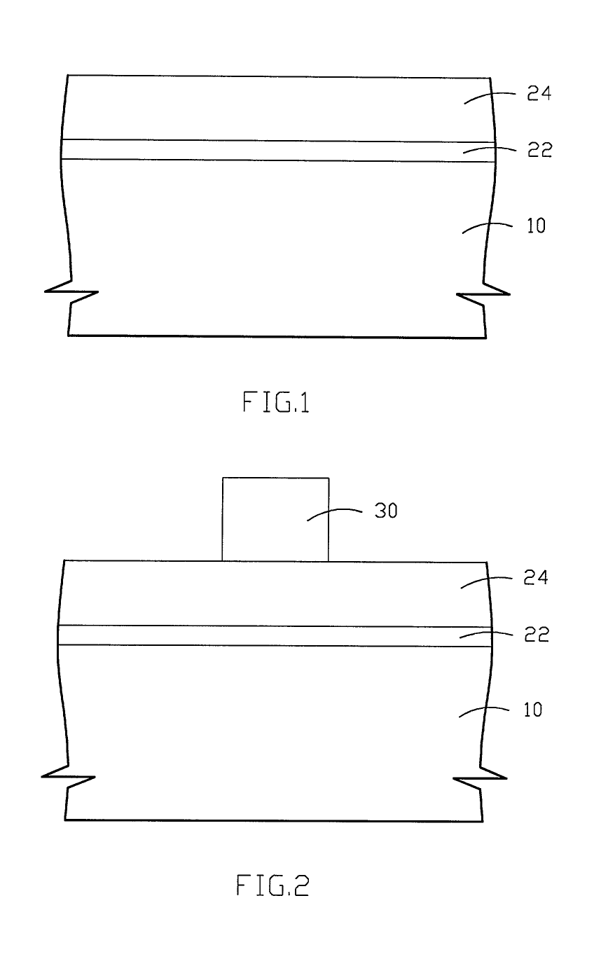

Referring to FIG. 1, a gate oxide layer 22 is formed on a silicon substrate 10 of a wafer and a polysilicon layer 24 is formed on the gate oxide layer 22. Referring to FIG. 2, after deciding the place of the polysilicon gate, the mask layer 30, which is located at the place of the polysilicon gate, is formed on the polysilicon layer 24. After the etching process to remove the superfluous gate oxide layer 22 and polysilicon layer 24 and removing the mask layer 30 by using the chemical solvent, a polysilicon gate is formed on the silicon substrate 10 of the wafer.

FIG. 3 shows a diagram in the polysilicon gate. The polysilicon gate 20 comprises a polysilicon layer 24 and a gate oxide layer 22. The gate oxide layer 22 is formed by using a thermal oxide process to be a pad oxide layer on the silicon substrate 10. The polysilicon layer 24 is formed on the gate oxide layer 22.

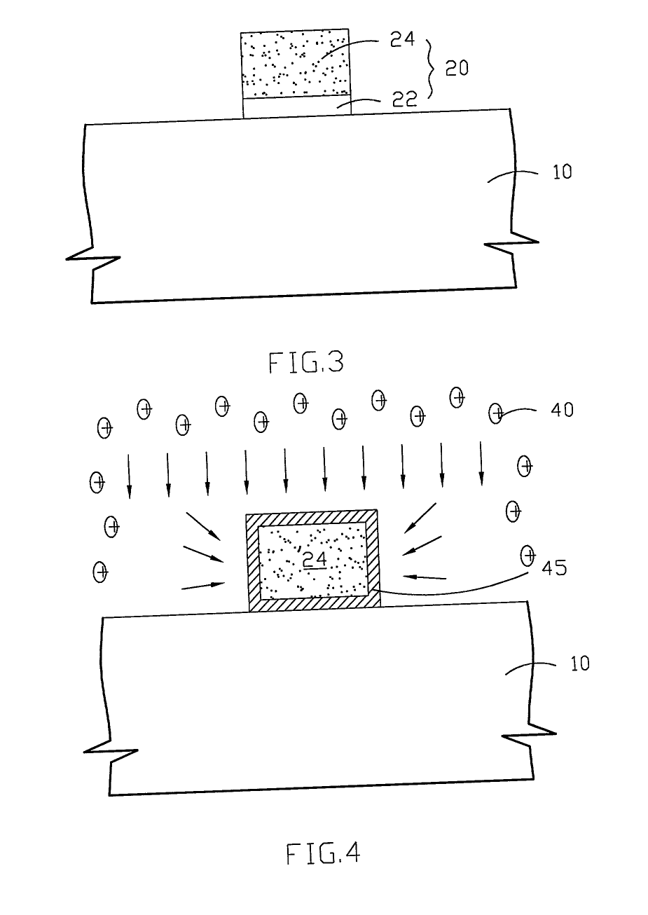

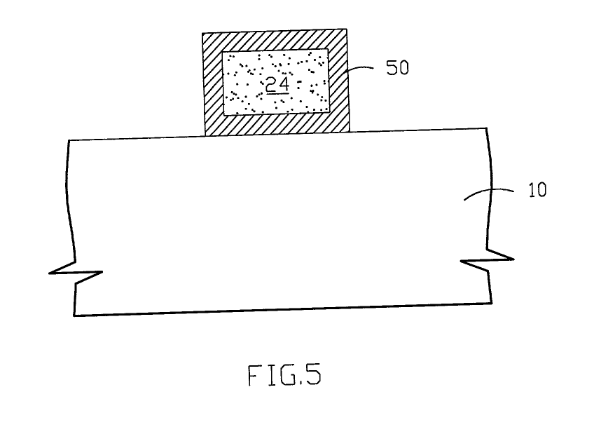

Referring to FIG. 4, the nitrogen ions 40 is implanted to the surface of the polysilicon gate 20. The nitrogen ions 40 is implanted in any direction to the surface of the polysilicon gate 20 and react to the silicon atoms which are inside the polysilicon gate 20 to become silicon nitride. Therefore, a silicon nitride layer 45 can be formed over the polysilicon gate 20. The nitrogen ions 40 also can enter to the bottom of the polysilicon gate 20 by implantation mode and form the silicon nitride layer 45 at the bottom of the polysilicon gate 20 or can react to the gte oxide layer 22, which is at the bottom of the polysilicon gate 20, to become a silicon oxynitride layer.

There are a lot of methods in the nitrogen ion implantation. The nitrogen ions 40 can be implanted into the surface of the polysilicon gate 20 by using the ion bombardment or the plasma implantation. In general, the implanted depth of the nitrogen ions 40 is controlled by the energy of the implanted nitrogen ions 40 to avoid the nitrogen ions 40 to be implanted over depth to affect the original dimension of the polysilicon gate 20. The energy of the implanted nitrogen ions 40 is about 200 to 5000 electric voltage (eV) in usual. The dosage of the implanted nitrogen ions 40 is about per cubic centimeter 1E14 to 1E17 pieces of the nitrogen ions 40. The proceeding time of the nitrogen ions implantation process is different following the different implantation modes. The proceeding time of the nitrogen ions implantation process is about 120 to 1800 seconds.

The wafer, which has passed through the nitrogen ions 40 implantation process, is placed into the chamber of the furnace to proceed a thermal oxide process. When the temperature of the chamber is about b 600 to 700° C., oxygen is transported to the chamber and the temperature of the chamber is increased. When the temperature of the chamber is about 750 to 900° C. and is held about 120 to 240 seconds, the temperature of the chamber is decreased and the wafer is taken out from the chamber. Then the thermal oxide process is finished. Referring to FIG. 5, at this time, a mixed layer, which comprises silicon oxynitride and silicon dioxide, is formed over the polysilicon gate to be the buffer layer of the polysilicon gate. The whole thermal oxide process is about 10800 to 12600 seconds. The thickness of the mixed layer, which comprises silicon oxynitride and silicon dioxide, is about 10 to 50 angstroms.

In the thermal oxide process, the oxygen atoms will permeate to the silicon nitride layer 45, which is on the surface of the polysilicon gate 20, and proceed a reaction process to form the mixed layer 50, which comprises silicon oxynitride and silicon dioxide, to be the buffer layer. The main objective of the initial stage in the heating process is to make the silicon nitride layer 45 which is over the surface of the polysilicon gate 20 harder. When oxygen is transported to the chamber to proceed the thermal oxide process, the oxygen atoms can not pierce through the silicon nitride layer 45 which is over the surface of the polysilicon gate 20. Therefore, the oxygen atoms just proceed the oxide process with the surface of the silicon nitride layer 45 to form the mixed layer 50, which comprises silicon oxynitride and silicon dioxide. The oxygen atoms can not enter to inside the polysilicon gate to react with the silicon atoms and the original dimension of the polysilicon gate can not be decreased to further affect the qualities of the semiconductor elements.

In the present embodiment, the furnace is used to be a apparatus in the thermal oxide process. The structure of buffer layer, which is formed over the polysilicon gate 20, is harder in the slowly increasing temperature process. This condition can make the impurities not pierce through the buffer layer to inside the polysilicon gate in the making spacer process and not affect the electricity of the polysilicon gate. This condition can also not cause the reducing region of the polysilicon gate 20 and can not limit the region of the invention.

The mixed layer 50, which comprises silicon oxynitride and silicon dioxide, is used to be a gate oxide layer to avoid the oxygen atoms permeating to the gate oxide layer 22 and to avoid generating the bird's beak region in the gate oxide layer 22. The mixed layer 50, which comprises silicon oxynitride and silicon dioxide, can further avoid the oxygen atoms pierce through the gate oxide layer 22 to the silicon substrate 10 which is under the gate oxide layer 22 to react with the silicon atoms to enlarge the region of the source/drain in the thermal oxide process.

Using the present invention method, the mixed layer 50, which comprises silicon oxynitride and silicon dioxide, is formed over the polysilicon gate 20 to be the buffer layer. This buffer layer can combine amply with the polysilicon gate 20 and the spacer to be a finer interface. This condition can avoid the electric leakage and stress defects to be generated in the polysilicon gate 20. Using this present invention method can further quickly form the buffer layer over the surface of the polysilicon gate 20 to raise the throughput and to decrease the production cost.

In accordance with the present invention, the present invention provides a method for forming a mixed layer, which comprises silicon oxynitride and silicon dioxide, to be the buffer layer over a polysilicon gate by using a nitrogen ions implantation to form a silicon nitride layer over the polysilicon gate and passing through a thermal oxide process. The buffer layer can prevent the oxygen atoms permeating to inside the polysilicon gate to affect its dimension and further to affect the electricity of the semiconductor elements. The buffer layer can also combine amply with the polysilicon gate and the spacer to avoid the electric leakage and stress defects to be generated in the polysilicon gate. The buffer layer can further restrain the oxygen atoms to pierce through the gate oxide layer, which is at the bottom of the polysilicon gate, and silicon substrate and can reduce the bird's beak area in the gate oxide layer and the diffusion region of the source/drain. The present invention method can increase the qualities of the semiconductor elements. The present invention method can decrease the steps of the traditional method and can raise the proceeding rate of the process and the throughput.

Although specific embodiments have been illustrated and described, it will be obvious to those skilled in the art that various modifications may be made without departing from what is intended to be limited solely by the appended claims.

What is claimed is:

1. A method for forming a buffer layer over a polysilicon gate, said method comprises:
providing a wafer, said wafer comprises a substrate;
forming a gate oxide layer on said substrate;
forming a polysilicon layer on said gate oxide layer;
deciding a place of said polysilicon gate and forming a mask layer at said place;
etching part of said gate oxide layer and said polysilicon layer to form a shape of said polysilicon gate;
implanting a nitrogen ion to a surface of said polysilicon gate;
placing said wafer to a chamber and increasing a temperature of inside said chamber; and
transporting a oxygen to said chamber to form said buffer layer.

2. The method according to claim 1, wherein said a material of said gate oxide layer is silicon dioxide.

3. The method according to claim 1, wherein said a material of said surface is silicon nitride.

4. The method according to claim 1, wherein a energy of said nitrogen ion is about 200 to 5000 electric voltage.

5. The method according to claim 1, wherein a dosage of said nitrogen ion is about per cubic centimeter 1E14 to 1E17 pieces of said nitrogen ion.

6. The method according to claim 1, wherein said buffer layer comprises a silicon oxynitride and a silicon dioxide.

7. A method for forming a buffer layer over a polysilicon gate, said method comprises:
providing a wafer, said wafer comprises a substrate;
forming said polysilicon gate on said substrate, said polysilicon gate comprising a gate oxide layer and a polysilicon layer;
implanting a nitrogen ion to said polysilicon gate to form a silicon nitride layer;
placing said wafer to a chamber and increasing a temperature of inside said chamber; and
transporting a gas to said chamber to form said buffer layer.

8. The method according to claim 7, wherein said a material of said gate oxide layer is silicon dioxide.

9. The method according to claim 7, wherein a energy of said nitrogen ion is about 200 to 5000 electric voltage.

10. The method according to claim 7, wherein a dosage of said nitrogen ion is about per cubic centimeter 1E14 to 1E17 pieces of said nitrogen ion.

11. The method according to claim 7, wherein said buffer layer comprises a silicon oxynitride and a silicon dioxide.

12. The method according to claim 11, wherein a thickness of said buffer layer is about 10 to 50 angstroms.

13. The method according to claim 7, wherein said gas comprises a oxygen.
